(19) United States
(12) Patent Application Publication
(10) Pub. No.: US 2011/0260275 A1
(43) Pub. Date: Oct. 27, 2011

(54) ELECTRONIC DEVICE PACKAGE AND METHOD OF MANUFACTURING THE SAME

(75) Inventor: Young Sang CHO, Chungcheongbuk-Do (KR)

(73) Assignee: OPTOPAC CO., LTD, Chungcheongbuk-Do (KR)

(21) Appl. No.: 13/079,008

(22) Filed: Apr. 3, 2011

(30) Foreign Application Priority Data
Apr. 23, 2010 (KR) 10-2010-0037978

(51) Int. Cl. H01L 31/0232; H01L 31/18

(52) U.S. Cl. 257/432; 438/64; 257/E31.127

(57) ABSTRACT

Provided are an electronic device package and a method of manufacturing the same. The electronic device package includes an electronic device including a polymer layer and a passivation layer configured to protect a device layer, a substrate assembly facing the electronic device, and a sealing ring formed in a closed loop between the electronic device and the substrate assembly and surrounding a sealing region. At least one side surface of the sealing ring contacts the polymer layer, and the sealing ring is disposed on the passivation layer. A polymer layer such as a microlens and a color filter is removed from a region provided with a sealing ring to form the sealing ring on a passivation layer, thereby making the sealing ring and joints the same height, thus preventing an electrical defect.

### CROSS-REFERENCE TO RELATED APPLICATION

This application claims priority to Korean Patent Application No. 10-2010-0037978 filed on Apr. 23, 2010 and all the benefits accruing therefrom under 35 U.S.C. §119, the contents of which are incorporated by reference in their entirety.

### BACKGROUND

The present disclosure relates to an electronic device package and a method of manufacturing the electronic device package, and more particularly, to an electronic device package and a method of manufacturing the electronic device package, which make it possible to protect the electronic device package from a contaminant and securely couple an electronic device to a substrate.

Photo sensors, which are semiconductor devices configured to capture an image of an object, are widely used in various fields. For example, digital cameras, camcorders, and mobile phones may include photo sensors.

Such a photo sensor includes a pixel region in its central portion, and terminals in its peripheral portion. The pixel region senses images, and the terminals transmit or receive electrical signals of images taken at pixels or other signals, or supply power. A photo diode, a passivation layer, a color filter, and a microlens are stacked in the pixel region. The photo sensor is packaged, for example, using a chip scale package (CSP) method. In the chip scale package method, a photo sensor chip and a transparent substrate such as a glass substrate are adhered to each other and are packaged to be installed on a camera module, thereby efficiently miniaturizing a photo sensor package.

Meanwhile, dust or moisture may be introduced to a photo sensor package. In this case, the dust or moisture may be adhered to a pixel region to cause a defect of a captured image. In addition, the moisture introduced to the photo sensor package may degrade a color filter or a microlens of a photo sensor chip. Thus, the pixel region of photo sensor packages is securely sealed to prevent the introduction of dust or moisture after the packaging.

To this end, sealing rings are used. Such a sealing ring surrounds the pixel region, and is formed of a resin such as epoxy. However, since dust or moisture can pass through a resin, the sealing ring formed of a resin may incompletely seal the pixel region. When a photo sensor chip is adhered to a transparent substrate, the pixel region is maintained at high pressure. At this point, the sealing ring of a resin may be blown out by the high pressure of the pixel region.

To address a defect (e.g. a blowout) of a sealing ring formed of a resin, the sealing ring may be formed of a solder material such as SnAg, and have an air vent for discharging air when the solder material is adhered to an object. To form the air vent, the sealing ring may have a spiral structure that one end thereof surrounds another end. However, when a sealing ring has an air vent, dust or moisture may be introduced along the air vent, and thus, it is difficult to completely block dust and moisture. In addition, an inner pressure of the sealing ring may increase in a high temperature process such as a sub-mount process to be performed later, and thus, moisture or gas may diffuse through the lower side of the sealing ring and may contact a color filter and a microlens of a photo sensor chip.

In addition, a sealing ring may be formed of SnAg having a low melting point in a closed loop, but SnAg is liquefied in a high temperature process such as a sub-mount process to cause a blowout due to inner pressure of a hollow part. In addition, a sealing ring and flip chip joints may be formed at the same time. In this case, the sealing ring is formed on a microlens, but the flip chip joints are disposed on a passivation layer outside the sealing ring. Thus, when the sealing ring contacts a transparent substrate, the flip chip joints are spaced apart from the transparent substrate by the thicknesses of the microlens and the color filter. Thus, since the flip chip joints incompletely contact the transparent substrate, it is difficult to supply power to the photo sensor chip, thereby causing an electrical defect of a photo sensor package.

### SUMMARY

The present disclosure provides an electronic device package that prevents the introduction of a foreign substance to a sealing region of an electronic device including a pixel region of a photo sensor chip and includes a sealing ring having a closed loop shape and resistant to a blow out, and a method of manufacturing the electronic device package.

The present disclosure also provides an electronic device package that includes a sealing ring having a stacked structure of a sealing layer and an adhesion layer in a closed loop to prevent the introduction of a foreign substance and a blow out, and a method of manufacturing the electronic device package.

The present disclosure also provides an electronic device package and a method of manufacturing the electronic device package, which removes a polymer layer such as a microlens and a color filter in a region provided with a sealing ring to form the sealing ring on a passivation layer, thereby further preventing the introduction of moisture or a foreign substance, and makes the sealing ring and flip chip joints the same height to prevent an electrical defect due to poor contact of the flip chip joints.

In accordance with an exemplary embodiment, an electronic device package includes: an electronic device including a polymer layer and a passivation layer configured to protect a device layer; a substrate assembly facing the electronic device; and a sealing ring formed in a closed loop between the electronic device and the substrate assembly and surrounding a sealing region, wherein at least one side surface of the sealing ring contacts the polymer layer, and the sealing ring is disposed on the passivation layer.

The electronic device may include a photo sensor, a micro electro mechanical systems (MEMS) device, a silicon-based device, a GaAs-based device, or an InP-based device.

The substrate assembly may include a transparent substrate, a translucent substrate, or an opaque substrate, with respect to light, and the substrate assembly may include a conductive substrate, a semiconductor substrate, or an insulating substrate, with respect to electricity.

The passivation layer may be disposed on an entire region of the electronic device, and the polymer layer may be disposed in the sealing region on the passivation layer.

The passivation layer may be formed of a single layer or stacked layers comprising one of silicon oxide (SiO₂), tetraethoxysilane (TEOS), silicon nitride (SiN), silicon carbide (SiC), silicon oxynitride (SiON), a diamond mixture, and mixtures thereof.

The polymer layer may include a color filter and a microlens.

The sealing ring may include a stacked structure of a sealing layer and an adhesion layer.

The adhesion layer may be formed by reacting a low melting point material layer having a lower melting point than that of the sealing layer with the sealing layer, and may include an intermetallic compound.

The sealing layer may include at least one of Cu, Au, Sn, SnAg, SnAgCu, Ag, and Ni.

The low melting point material layer may include at least one of Sn, SnAg, a stacked structure of Ti/In/Au, Bi, and In.

The sealing layer and the low melting point material layer may include Cu and Sn, Cu and SnAg, Au and a stacked structure of Ti/In/Au, Sn and Bi, SnAg and Bi, SnAgCu and Bi, Ag and In, or Ni and Sn, respectively.

The adhesion layer may include one of CuSn, CuSnAg, AuIn, SnBi, Sn, AgBi, SnAgCuBi, AgIn, and NiSn.

The electronic device package may further include a joint disposed outside the sealing ring and contacting the passivation layer.

The electronic device package may further include a joint disposed inside the sealing ring, wherein side surfaces of the joint contact the polymer layer, and a bottom surface of the joint contacts the passivation layer.

The electronic device package may further include a resin seal ring disposed outside the sealing ring.

In accordance with another exemplary embodiment, a method of manufacturing an electronic device package includes: forming an electronic device including a stacked structure of a passivation layer and a polymer layer n a substrate;
removing a portion of the polymer layer; stacking a sealing layer and a low melting point material layer on one of the electronic device and an substrate assembly in a region corresponding to the removed portion of the polymer layer; forming a sealing ring pad on one of the electronic device and the substrate assembly without the sealing layer and the low melting point material layer; bringing the electronic device in contact with the substrate assembly such that the low melting point material layer corresponds to the sealing ring pad; and forming an adhesion layer by melting the low melting point material layer and reacting the low melting point material layer with the sealing layer and the sealing ring pad.

The polymer layer may be removed in a closed loop.

The sealing layer and the low melting point material layer may be formed on the electronic device, and a joint may be spaced apart from the sealing layer and the low melting point material layer.

The joint, the sealing layer, and the low melting point material layer may be simultaneously formed of an identical material.

The adhesion layer may be heat-treated to have an intermetallic compound different from that of the low melting point material layer.

### BRIEF DESCRIPTION OF THE DRAWINGS

Exemplary embodiments can be understood in more detail from the following description taken in conjunction with the accompanying drawings, in which:

FIG. 1 is a plan view illustrating a photo sensor package in accordance with an exemplary embodiment;

FIG. 2 is a cross-sectional view taken along line A-A′ of FIG. 1;

FIG. 3 is a flowchart illustrating a method of manufacturing a photo sensor package in accordance with an exemplary embodiment;

FIGS. 4A through 4F are cross-sectional views in accordance with the method of FIG. 3;

FIGS. 5A and 5B are a plan view image and a cross-sectional image, which illustrate a sealing ring formed of SnAg and a blowout of the sealing ring in the related art;

FIG. 6 is a cross-sectional image illustrating a sealing ring formed using Cu and SnAg in accordance with an exemplary embodiment; and

FIG. 7 is a cross-sectional view illustrating a photo sensor package in accordance with another exemplary embodiment.

### DETAILED DESCRIPTION OF EXEMPLARY EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration. Like reference numerals refer to like elements throughout. It will also be understood that when a layer, a film, a region or a plate is referred to as being ‘on’ another one, it can be directly on the other one, or one or more intervening layers, films, regions or plates may also be present. Further, it will be understood that when a layer, a film, a region or a plate is referred to as being ‘under’ another one, it can be directly under the other one, and one or more intervening layers, films, regions or plates may also be present. In addition, it will also be understood that when a layer, a film, a region or a plate is referred to as being ‘between’ two layers, films, regions or plates, it can be the only layer, film, region or plate between the two layers, films, regions or plates, or one or more intervening layers, films, regions or plates may also be present.

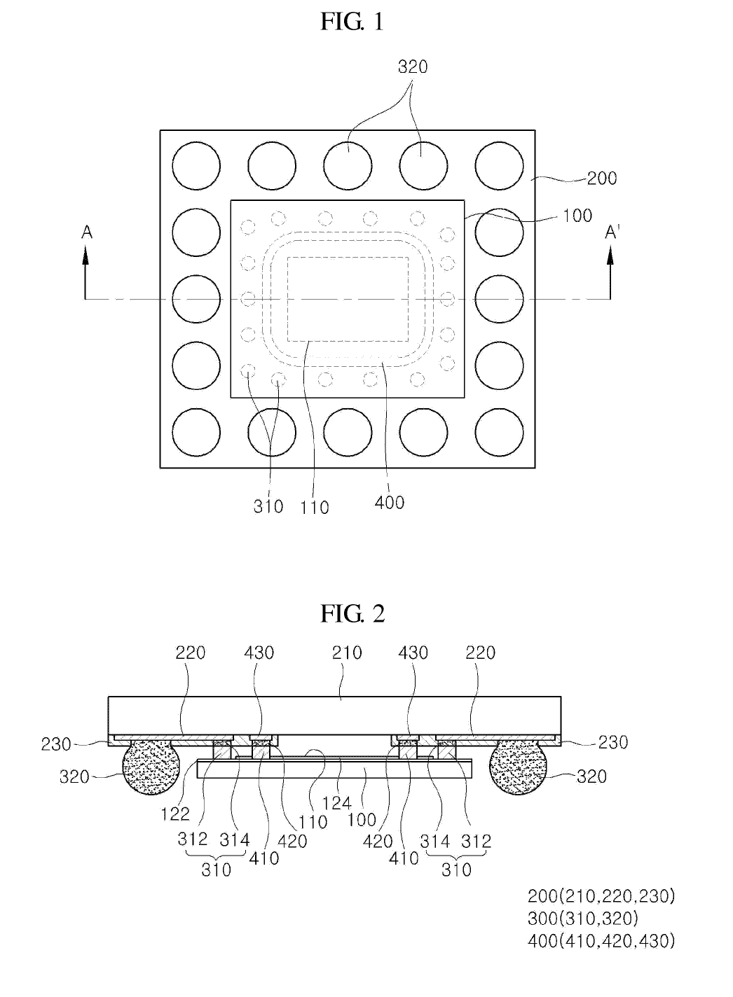

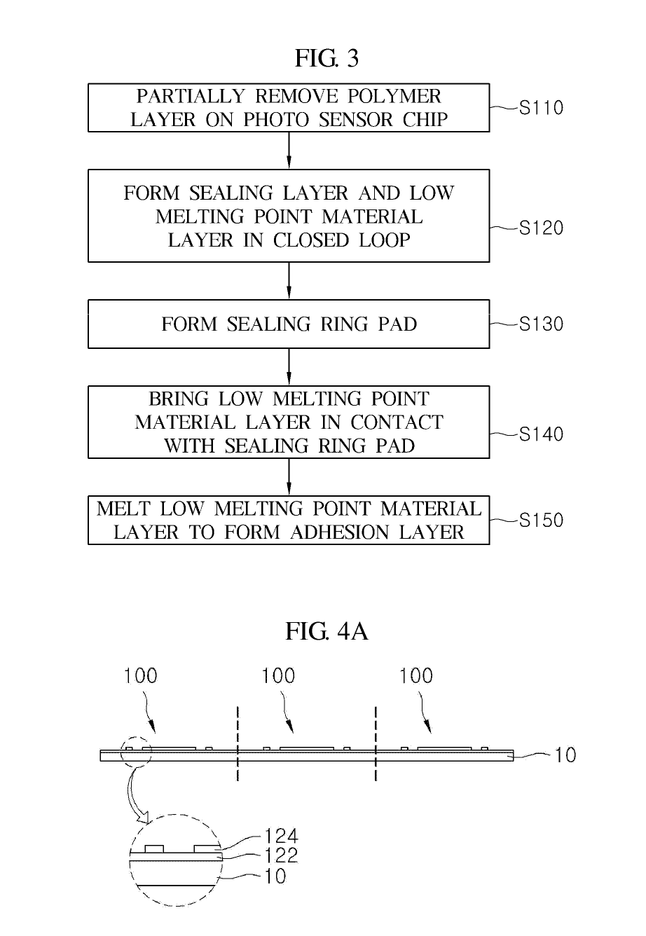

FIG. 1 is a plan view illustrating a photo sensor package in accordance with an exemplary embodiment. FIG. 2 is a cross-sectional view taken along line A-A′ of FIG. 1.

Referring to FIGS. 1 and 2, a photo sensor package in accordance with an exemplary embodiment includes a photo sensor chip 100 configured to sense an image, a substrate assembly 200 facing the photo sensor chip 100 and electrically connected to the photo sensor chip 100, a connection part 300 configured to electrically connect the photo sensor chip 100 to the substrate assembly 200, and a sealing ring 400 configured to prevent the introduction of a foreign substance to a pixel region 110 of the photo sensor chip 100.

The photo sensor chip 100 includes the pixel region 110 disposed in the central portion thereof to sense an image, and a terminal part (not shown) disposed in a peripheral portion thereof. The terminal part transmits an electrical signal of an image captured by the pixel region 110, or transmits and receives other signals, or supplies power. For example, the pixel region 110 may be formed by stacking a photovoltaic conversion layer (not shown) configured to convert light into an electric signal, a passivation layer 122 disposed on the photovoltaic conversion layer, and a polymer layer 124 disposed on the passivation layer 122. The photovoltaic conversion layer (not shown) may include a photo diode, a photo transistor, a photo gate, a pinned photo diode (PPD), and a combination thereof on a semiconductor substrate. A plurality of layers may be disposed on the photovoltaic conversion layer, and may include at least one layer including a metal line, and at least one interlayer insulation layer. The passivation layer 122 is disposed on the photovoltaic conversion layer and the layers on the photovoltaic conversion layer, and protects the photovoltaic conversion layer and a structure such as the metal line from external moisture. The passivation layer 122 may be disposed also in the peripheral portion including the terminal part, as well as in the pixel region 110. That is, the passivation layer 122 is formed entirely on a surface of the photo sensor chip 100. The passivation layer 122 may include one of silicon oxide (SiO₂), tetraethoxysilane (TEOS), silicon nitride (SiN), silicon carbide (SiC), silicon oxynitride (SiON), a diamond mixture, and mixtures thereof. Alternatively, the passivation layer 122 may be formed by stacking at least two of silicon oxide (SiO₂), tetraethoxysilane (TEOS), silicon nitride (SiN), silicon carbide (SiC), silicon oxynitride (SiON), a diamond mixture, and mixtures thereof. However, the materials of the passivation layer 122 are not limited thereto provided that a low structure is protected according to the characteristics of a device. The polymer layer 124 includes a color filter and a microlens. The color filter is disposed on the passivation layer 122 and has separate red, green, and blue colors. The microlens is disposed on the color filter to collect light to the photovoltaic conversion layer and improve sensitivity of the photovoltaic conversion layer. The color filter and the microlens are disposed in the pixel region 110 of the photo sensor chip 100. The sealing ring 400 is disposed on a predetermined region of the polymer layer 124. In accordance with the current embodiment, a portion of the polymer layer 124 provided with the sealing ring 400 is removed. That is, a portion of the polymer layer 124 is removed along the shape of the sealing ring 400, for example, along a closed loop to expose the passivation layer 122 at the lower side, and the sealing ring 400 contacts the passivation layer 122. Thus, when the sealing ring 400 and the connection part 300, particularly, the sealing ring 400 and joints 310 are formed at the same time, the sealing ring 400 and the joints 310 may have the same height. Thus, poor contact of the joints 310 due to a height difference occurring when the joints 310 and the sealing ring 400 are disposed on the passivation layer 122 and the polymer layer 124, respectively, can be prevented. A planarization film may be formed between the color filter and the microlens. The planarization film removes a height difference that may occur when the color filter is disposed on a region corresponding to the photovoltaic conversion layer. A portion of the planarization film where the sealing ring 400 is formed is also removed to expose the passivation layer 122.

The substrate assembly 200 includes a transparent substrate 210, a metal line 220 selectively disposed on a surface of the transparent substrate 210 on which the photo sensor chip 100 is mounted, and an insulating layer 230 disposed on the metal line 220 to insulate the metal line 220. The transparent substrate 210 is formed of a transparent material such as glass and plastic, and may be formed in a plate shape having a predetermined thickness. The surface of the transparent substrate 210 provided with the metal line 220 or a second surface of the transparent substrate 210 without the metal line 220 may be coated with an optical material for improving sensing or filtering of light within a desired wavelength band. For example, the second surface of the transparent substrate 210 to which light is incident may be coated with an infrared (IR) cutoff filter (not shown) for transmitting or blocking light of a specific wavelength band, or the IR cutoff film (not shown) may be attached thereto. The metal line 220 is disposed outside a region corresponding to the pixel region 110 on the first surface of the transparent substrate 210. The metal line 220 may be formed by patterning using a printing process, or be formed by depositing a metal and then patterning the metal using photo and etch processes. The insulating layer 230 is disposed on the metal line 220 to expose a predetermined region of the metal line 220. That is, the insulating layer 230 partially exposes the metal line 220 that is connected to the photo sensor chip 100 and a printed circuit board (not shown). Also, the insulating layer 230 may be formed by patterning using a printing process, or be formed by depositing an insulating material and then patterning the insulating material using photo and etch processes.

The connection part 300 includes the joints 310 for electrically connecting the photo sensor chip 100 to the substrate assembly 200, and solder balls 320 for electrically connecting the printed circuit board (not shown) to the substrate assembly 200. The joints 310 are disposed outside the sealing ring 400 between the substrate assembly 200 and the photo sensor chip 100. The joints 310 may be disposed in a predetermined region on the photo sensor chip 100. In more detail, the joints 310 may be disposed outside the pixel region 110, that is, on the passivation layer 122 out of the polymer layer 124. Alternatively, the joints 310 may be disposed inside the sealing ring 400. In this case, regions of the polymer layer 124 provided with the joints 310 are removed to form the joints 310 on the passivation layer 122. The joints 310 may include a stacked structure of a conductive layer 312 and an adhesion layer 314. The joints 310 may be the same in material and structure as the sealing ring 400, which will be described later. The conductive layer 312 may be formed of a conductive material such as copper. The adhesion layer 314 may be formed of a material such as SnAg having a lower melting point than those of the conductive layer 312 and the metal line 220 of the substrate assembly 200 to react with the conductive layer 312 and the metal line 220. That is, a low melting point material layer is melted at a predetermined temperature, that is, at a temperature equal to or greater than its melting temperature, and the melted low melting point material layer reacts with the conductive layer 312 and the metal line 220 of the substrate assembly 200, so as to form the adhesion layer 314. For example, SnAg that constitutes the low melting point material layer reacts with Cu that constitutes the conductive layer 312 and the metal line 220, so as to form CuSnAg that constitutes the adhesion layer 314. The solder balls 320 are melted to the metal line 220 of the substrate assembly 200 along the periphery of the photo sensor chip 100 to electrically connect the substrate assembly 200 to the printed circuit board. For example, the solder balls 320 are spaced a constant distance from one another along the periphery of the transparent substrate 210 that is tetragonal. At least one of the solder balls 320 may be replaced with at least one passive device (not shown). The passive device includes at least one of a decoupling capacitor, an inductor, a resistor, a varistor, and a filter, and removes a noise of a signal transmitted between the printed circuit board and the photo sensor chip 10.

The sealing ring 400 is disposed between the photo sensor chip 100 and the substrate assembly 200 to surround a sealing region including the pixel region 110 of the photo sensor chip 100. The sealing ring 400 disposed on the photo sensor chip 100 is attached to the substrate assembly 200, and is formed in the removed region of the polymer layer 124 constituting the pixel region 110. That is, the sealing ring 400 is formed on a portion of the passivation layer 122 exposed by partially removing the polymer layer 124. The sealing ring 400 prevents the introduction of a foreign substance into the sealing region between the substrate assembly 200 and the photo sensor chip 100. The sealing ring 400 includes a sealing layer 410 disposed on the photo sensor chip 100, and an adhesion layer 420 disposed on the sealing layer 410. Further, the sealing ring 400 may include a sealing ring pad 430 disposed in a predetermined region of the transparent substrate 210 and adhered to the adhesion layer 420. The sealing ring 400 may be formed in a closed loop to surround the pixel region 110. That is, an inner space defined by the transparent substrate 210, the photo sensor chip 100, and the sealing ring 400 is separated and sealed from the outside, and the pixel region 110 is disposed in the inner space. The sealing layer 410 is formed in a closed loop to surround the pixel region 110, and the adhesion layer 420 may be formed on the sealing layer 410. The insulating layer 230 is disposed on the sealing ring pad 430, and partially exposes the sealing ring pad 430. The sealing ring pad 430 may be formed of the same material through the same process as those of the metal line 220 of the substrate assembly 200. At this point, the sealing ring pad 430 is spaced apart from the metal line 220. Alternatively, the sealing layer 410 may be disposed on the transparent substrate 210, and the sealing ring pad 430 may be disposed on the photo sensor chip 100. The sealing layer 410 and the sealing ring pad 430 may be formed of a metal such as copper. The adhesion layer 420 may be fabricated by forming a lower melting point material layer having a lower melting point than those of the sealing layer 410 and the sealing ring pad 430, and by reacting the lower melting point material layer with the sealing layer 410 and the sealing ring pad 430. For example, the sealing layer 410 may include at least one of Cu, Au, Sn, SnAg, CuSnAg, Ag, and Bi, or an alloy thereof, and the lower melting point material layer may include at least one of Sn, SnAg, a stacked structure of Ti/In/Au, Bi, and In, or an alloy thereof. That is, the low melting point material layer may be formed of a material having a lower melting point than that of the sealing layer 410. Furthermore, the sealing layer 410 may be formed of a material that would otherwise constitute the low melting point material layer. In this case, the melting point of a material constituting the low melting point material layer is lower than that of the material constituting the sealing layer 410. For example, the sealing layer 410 and the low melting point material layer may include Cu and Sn, Cu and SnAg, Au and a stacked structure of Ti/In/Au, Sn and Bi, SnAg and Bi, CuSnAg and Bi, Ag and In, or Ni and Sn, respectively. The low melting point material layer is melted at a predetermined temperature and reacts with the sealing ring pad 430 and the sealing layer 410 to form the adhesion layer 420. That is, the low melting point material layer is melted at its melting temperature or greater, and elements in the melted low melting point material layer react with elements of the sealing ring pad 430 and the sealing layer 410 to form the adhesion layer 420. That is, the adhesion layer 420, which is physically/chemically different from the sealing layer 410, the sealing ring pad 430, and the low- melting point material layer, may be formed of an intermetallic compound having a predetermined composition ratio, and has a higher melting point than that of the low melting point material layer. For example, when the sealing layer 410 and the sealing ring pad 430 are formed of Cu, and the low melting point material layer is formed of SnAg, SnAg is melted to react with Cu at the upper and lower sides, thereby forming the adhesion layer 420 of CuSnAg. The adhesion layer 420 is solidified, and thus, the sealing layer 410 and the sealing ring pad 430 are securely adhered to the adhesion layer 420. Accordingly, the photo sensor chip 100 is coupled to the substrate assembly 200. The adhesion layer 420 formed as described above has a higher melting point than that of the low melting point material layer. For example, CuSnAg has a melting temperature ranging from approximately 400° C. to approximately 500° C. In this case, CuSnAg is not melted in a reflow process at a temperature of approximately 230° C., so as to prevent a defect such as a blowout due to pressure. The material of the adhesion layer 420 may be determined according to elements constituting the low melting point material layer, the sealing layer 410, and the sealing ring pad 430. For example, the adhesion layer 420 may be formed of CuSn, CuSnAg, AuIn, SnBi, Sn, AgBi, CuSnAgBi, AgIn, or NiSn. The thickness of the sealing layer 410 may be adjusted according to a distance between the photo sensor chip 100 and the substrate assembly 200. For example, the sealing layer 410 may have a thickness ranging from approximately 6 μm to approximately 100 μm, preferably, a thickness of approximately 30 μm. The low melting point material layer may have a thickness ranging from approximately 2 μm to approximately 12 μm, preferably, a thickness of approximately 8 μm. The low melting point material layer may have a thickness to be completely transformed to the adhesion layer 420. That is, the low melting point material layer may have a thickness to be entirely transformed to the adhesion layer 420 of an intermetallic compound having different characteristics from those of the low melting point material layer. Thus, the low melting point material layer may have any thickness provided that the low melting point material layer is entirely transformed to the adhesion layer 420 by completely reacting with the sealing layer 410 and the sealing ring pad 430. If the low melting point material layer is too thin, the adhesion layer 420 is also thin, and thus, may be poorly adhered to the substrate assembly 200. If the low melting point material layer is too thick, the low melting point material layer may be partially transformed to the adhesion layer 420. In this case, a residue of the low melting point material layer is melted again at a high temperature process such as a sub-mount process, and an inner pressure of the low melting point material layer increases to cause a blowout. That is, although a melting temperature or a melting time increase, the low melting point material layer may be partially melted, and a residue of the low melting point material layer may be present within a predetermined thickness without constituting the adhesion layer 420, which may cause a defect in a process to be performed later. Thus, the low melting point material layer may have a thickness to be securely adhered between the photo sensor chip 100 and the substrate assembly 200 and be entirely transformed to the adhesion layer 420.

The printed circuit board (not shown) may be connected to the solder balls 320 through connection pads, and a circuit pattern is printed on the printed circuit board (not shown), so as to supply a driving voltage and a driving current from the outside to the photo sensor chip 100 through the substrate assembly 200. The printed circuit board may have any structure such as a metal printed circuit board and a flexible printed circuit board in the form of a single or multi layer to supply a driving voltage and a driving current from the outside to the photo sensor chip 100.

As described above, in accordance with the embodiment, since the sealing ring 400 is disposed on the region formed by partially removing the polymer layer 124 constituting the pixel region 110, the sealing ring 400 and the joints 310 can be disposed at the same height. Thus, when the joints 310 and the sealing ring 400 are formed at the same time, an electrical defect due to poor contact that would occur otherwise between the joints 310 and the substrate assembly 200 can be prevented.

Since the sealing layer 410 and the adhesion layer 420 are stacked to form the sealing ring 400, and the adhesion layer 420 securely adheres the sealing layer 410 to the sealing ring pad 430 on the transparent substrate 210, the photo sensor chip 100 can be securely adhered to the substrate assembly 200. A lower melting point material having a lower melting point than those of the sealing layer 410 and the sealing ring pad 430 is melted and reacts with the sealing layer 410 and the sealing ring pad 430 to form the adhesion layer 420. Thus, since the sealing layer 410 having a high melting point is not melted at a high temperature process such as a sub-mount process to be performed later, a defect such as a blowout of the sealing ring 400 can be prevented. Accordingly, the sealing ring 400 can maintain a closed loop shape, and the introduction of a foreign substance such as dust and moisture from the outside can be efficiently prevented.

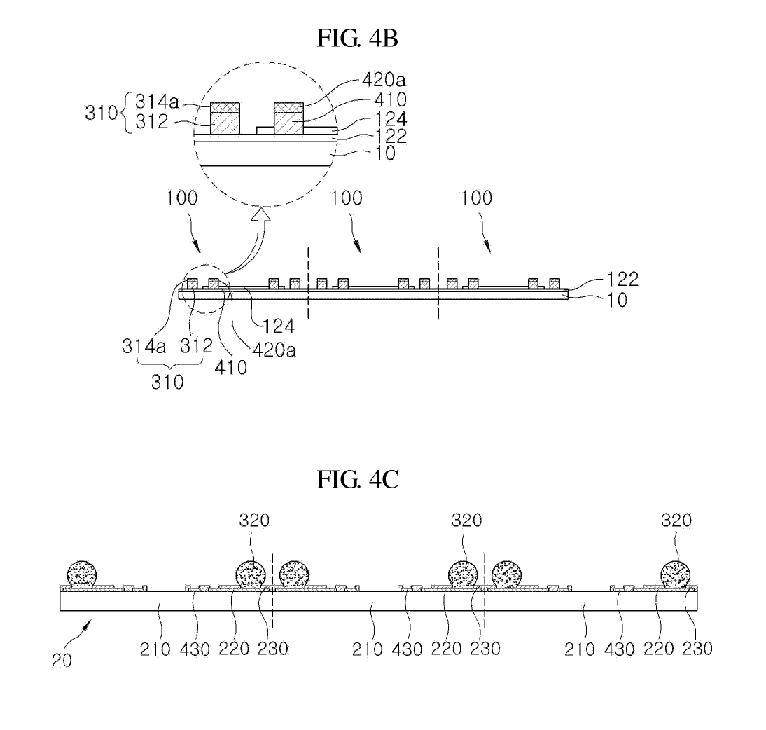

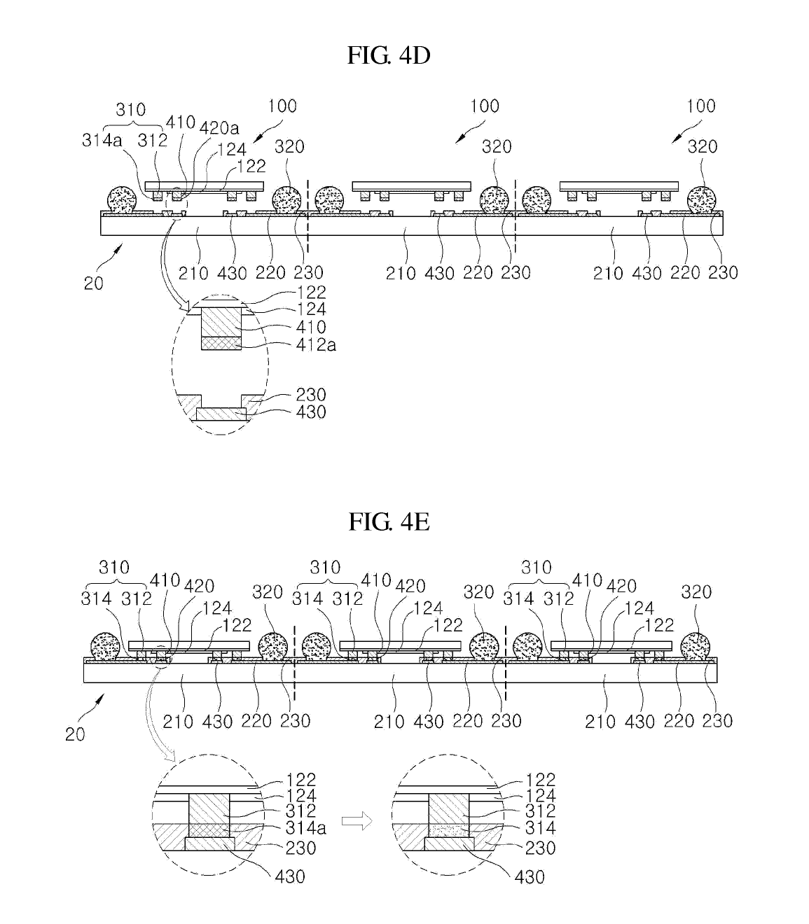

Referring to FIG. 3, in a method of manufacturing the photo sensor package in accordance with the embodiment, a portion of a polymer layer is removed on a photo sensor chip in operation S110, a sealing layer and a low melting point material layer are formed in a closed loop on one of the photo sensor chip and a substrate assembly in operation 5120, a sealing ring pad is formed on one of the photo sensor chip and the substrate assembly in a region corresponding to the sealing layer and the low melting point material layer in operation S130, the low melting point material layer disposed on the photo sensor chip or the substrate assembly is brought in contact with the sealing ring pad in operation 5140, and the low melting point material layer is melted at its melting point or greater and reacts with the sealing layer and the sealing ring pad to form an adhesion layer in operation S150. The method of manufacturing the photo sensor package in accordance with the embodiment will now be described in more detail with reference to FIGS. 4A through 4F.

FIGS. 4A through 4F are cross-sectional views illustrating a method of manufacturing a photo sensor package in accordance with an embodiment.

Referring to FIG. 4A, the photo sensor chip 100 is provided in plurality, and a photo sensor wafer 10 includes the photo sensor chips 100. Each of the photo sensor chips 100 has a pixel region for sensing an image in the central portion thereof, and a terminal part at the periphery of the pixel region. A photovoltaic conversion layer including, for example, a plurality of photo diodes for converting light into an electrical signal, and a metal line layer including at least one layer are formed in the pixel region. The passivation layer 122 is entirely formed in the pixel region including the photovoltaic conversion layer. The polymer layer 124 such as a color filter and a microlens is formed on the passivation layer 122. At this point, the polymer layer 124 may be formed only in a region provided with the photovoltaic conversion layer, that is, only in the pixel region 110. A portion of the polymer layer 124 of the photo sensor chip 100 is removed. The removed portion of the polymer layer 124 is a region provided with the sealing ring 400, and has a shape corresponding to the shape of the sealing ring 400, for example, may have a closed loop shape.

Referring to FIG. 4B, the conductive layer 312 and the sealing layer 410 are formed on the photo sensor wafer 10 including the photo sensor chips 100, and low melting point material layers 314a and 420a are formed on the conductive layer 312 and the sealing layer 410, respectively. The conductive layer 312 and the low melting point material layer 314a are used to form joints, and the sealing layer 410 and the low melting point material layer 420a are used to form a sealing ring. The conductive layer 312 may be spaced a predetermined distance from the sealing layer 410, and the sealing layer 410 may be formed in a closed loop. That is, the sealing layer 410 may be formed along the removed portion of the polymer layer 124 of the photo sensor chip 100, and the conductive layer 312 may be formed on the passivation layer 122 outside the pixel region 110 out of the polymer layer 124. Thus, the sealing layer 410 and the conductive layer 312 are formed at the same height. The low melting point material layers 314a and 420a are formed of materials having lower melting points than those of the conductive layer 312 and the sealing layer 410. For example, the conductive layer 312 and the sealing layer 410 may include Cu, Au, Sn, SnAg, CuSnAg, Ag, or Ni, and the low melting point material layers 314a and 420a may include Sn, SnAg, a stacked structure of Ti/In/Au, Bi, or In. The low melting point material layers 314a and 420a may be formed using materials that would otherwise constitute the conductive layer 312 and the sealing layer 410. In this case, the melting points of materials constituting the conductive layer 312 and the sealing layer 410 are lower than the melting points of the materials used to form the low melting point material layers 314a and 420a. For example, the conductive layer 312 or the sealing layer 410, and the low melting point material layer 314a or 420a may be formed by stacking Cu and Sn, Cu and SnAg, Au and a stacked structure of Ti/In/Au, Sn and Bi, SnAg and Bi, SnAgCu and Bi, Ag and In, or Ni and Sn. The conductive layer 312, the sealing layer 410, and the low melting point material layers 314a and 420a may be formed using an electroplating or printing method. An adhesion layer may be formed on the photo sensor wafer 10 to increase coupling force between the photo sensor wafer 10 and both the conductive layer 312 and the sealing layer 410. A seed layer may be formed on the adhesion layer to improve the electroplating with the conductive layer 312 and the sealing layer 410.

A process for a transparent wafer 20, which is performed separately from the photo sensor wafer 10, will now be described with reference to FIG. 4C. A batch process may be performed, in which the transparent substrate 210 as a unit substrate may be formed in plurality using the transparent wafer 20 having a large area. The transparent wafer 20 has predetermined transmissivity, thermal stability, mechanical durability, and chemical stability. A typical optical glass may be used as the transparent wafer 20 for a photo sensor configured to sense the band of visible light, thereby achieving mass production at low costs. An optical wafer may be formed on at least one surface of the transparent wafer 20. For example, the transparent substrate 210 may be coated with an IR cutoff filter (not shown) for transmitting or blocking light of a specific wavelength band, or an IR cutoff film (not shown) may be attached thereto, or an anti-reflection coating layer for increasing transmissivity within the band of visible light may be formed thereon. At least one metal line 220 and at least one insulating layer 230 are formed on the transparent wafer 20 formed as described above. The sealing ring pad 430 may be spaced apart from the metal line 220. That is, the metal line 220 and the sealing ring pad 430 are formed on a surface of the transparent wafer 20, and the insulating layer 230 is formed on the transparent wafer 20 to cover at least one portion of the metal line 220 and at least one portion of the sealing ring pad 430, so that at least one portion of the metal line 220 and at least one portion of the sealing ring pad 430 can be exposed. As a result, electrical input/output contact terminals and electrical lines electrically connecting to the contact terminals are formed. The metal line 220 and the sealing ring pad 430 may be formed of the same material through the same process. For example, the metal line 220 and the sealing ring pad 430 may be formed by depositing a metal layer on the surface of the transparent substrate 210 through sputtering and then etching the metal layer through photo and etch processes, or be formed by patterning a metal layer through electroplating. The insulating layer 230 may be formed of an insulating material such as a silicon oxide or a silicon nitride. To this end, the insulating material is deposited and then is patterned through a photo or etch process. The insulating layer 230 exposes at least one portion of the metal line 220 and at least one portion of the sealing ring pad 430. The sealing ring pad 430 is formed in a closed loop on a region corresponding to the sealing layer 410 and the low melting point material layer 420a on the photo sensor wafer 10. The solder balls 320 may be formed on the transparent substrate 210, as terminals for connecting the photo sensor package to a printed circuit board. To this end, flux is applied using a method such as printing on the periphery of the transparent wafer 20, for example, on the metal line 220, then, solders having a ball shape, that is, the solder balls 320 are attached to the flux, and then, a solder reflow process is performed. After the solder reflow process, a cleaning process is performed to remove a residue of the flux.

Accordingly, the photo sensor wafer 10 and the transparent wafer 20 are completed. Then, referring to FIG. 4D, the photo sensor wafer 10 are diced along dicing lines to separate the photo sensor chips 100. Then, a flip chip mounting apparatus is used to dispose the photo sensor chips 100 without a defect on the transparent substrates 210 of the transparent wafer 20. That is, the photo sensor chips 100 are disposed on the transparent wafer 20 such that the sealing layer 410 and the low melting point material layer 420a of the photo sensor chips 100 correspond to the sealing ring pads 430 of the transparent substrate 210.

Referring to FIG. 4E, the transparent wafer 20 provided with the photo sensor chips 100 is passed through a reflow oven at a melting point equal to or higher than the melting points of the low melting point material layers 314a and 420a. Accordingly, the low melting point material layers 314a and 420a are melted and liquefied, and elements of the low melting point material layer 314a react with elements of the conductive layer 312 and the metal lines 220, and elements of the low melting point material layer 420a react with elements of the sealing layer 410 and the sealing ring pads 430, thereby forming the adhesion layers 314 and 420. The sealing layer 410 and the low melting point material layer 420a may include Cu and Sn, Cu and SnAg, Au and a stacked structure of Ti/In/Au, Sn and Bi, SnAg and Bi, CuSnAg and Bi, Ag and In, or Ni and Sn, respectively, to form the adhesion layer 420 including CuSn, CuSnAg, AuIn, SnBi, Sn, AgBi, CuSnAgBi, AgIn, or NiSn. Thus, flip chip solder bumps (also denoted by 310) including the conductive layer 312 and the adhesion layer 314, and the sealing rings 400 including the sealing layer 410 and the adhesion layer 420 are formed.

Referring to FIG. 4F, the transparent wafer 20 is diced into unit packages to form the photo sensor package in accordance with the embodiment.

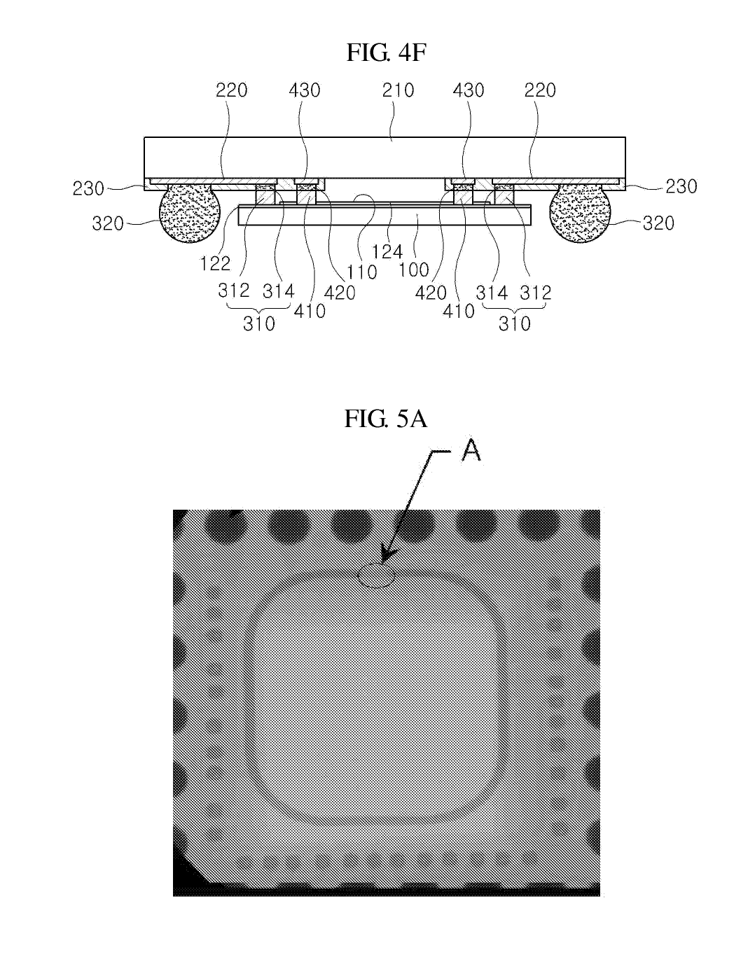

FIGS. 5A and 5B are a plan view image and a cross-sectional image, which illustrate a blowout of a closed loop-shaped sealing ring formed of SnAg in the related art. That is, a sealing ring may be formed of SnAg in a closed loop, but SnAg is liquefied in a high temperature process such as a sub-mount process to cause a blowout A due to inner pressure of a hollow part. In this case, the pressure of a sealing region is not maintained, and a foreign substance may be introduced from the outside through a portion where the blowout occurs, so as to cause a defect of a pixel.

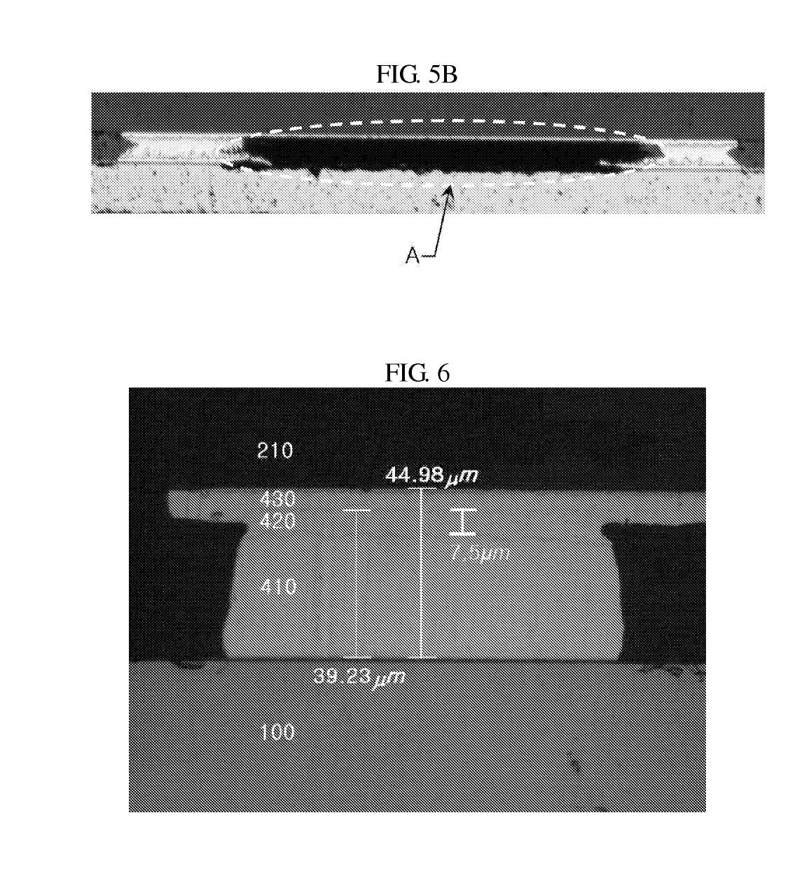

However, FIG. 6 is a cross-sectional image illustrating an adhesion layer of CuSn formed by reacting a low melting point material layer of SnAg with both a sealing layer of Cu and a sealing ring pad of Cu on a region without a polymer layer, in accordance with an embodiment. That is, the sealing ring pad 430 of Cu is formed on the transparent substrate 210, and the sealing layer 410 of Cu and a low melting point material layer of SnAg are formed on the photo sensor chip 100, and then, Cu reacts with SnAg at a temperature equal to or higher than the melting point of the low melting point material layer, to form the adhesion layer 420 of CuSnAg. Since the adhesion layer 420 has a melting point ranging from approximately 400° C. to approximately 500° C., the adhesion layer 420 is not melted in a process to be performed later, such as a reflow process that is performed at approximately 230° C., thereby preventing a blowout of the adhesion layer 420. Referring to FIG. 6, the photo sensor chip 100 or a passivation layer may be formed without a polymer layer such as a color filter and a microlens between the photo sensor chip 100 and the sealing layer 410.

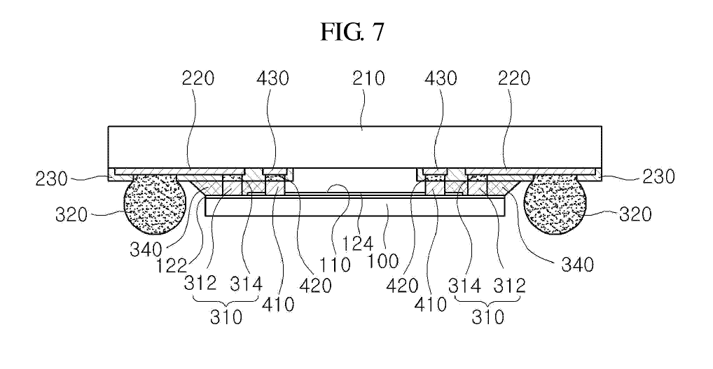

FIG. 7 is a cross-sectional view illustrating a photo sensor package in accordance with another embodiment. Resin seal rings 340 are disposed in a space between the sealing ring 400 and the joints 310 and in a space outside the joints 310 between the photo sensor chip 100 and the substrate assembly 200. The resin seal rings 340 prevent the introduction of a contaminant.

In accordance with the embodiments, the sealing ring 400 is disposed in the removed portion of the polymer layer 12 constituting the pixel region 110, so that the sealing ring 400 is disposed within the polymer layer 124. That is, the inner and outer surfaces of the sealing ring 400 contact the polymer layer 124. However, only the inner surface of the sealing ring 400, adjacent to the pixel region 110, may contact the polymer layer 124. That is, the sealing ring 400 may be disposed outside the pixel region 110 such that the inner surface of the sealing ring 400 contacts the polymer layer 124.

Although the photo sensor chip 100 is coupled to the substrate assembly 200 to form the photo sensor package in the embodiments, the present disclosure can be applied to various other electronic device packages than the photo sensor package. That is, the present disclosure can be applied to various electronic device packages including a substrate assembly coupled to an electronic device chip with a sealing ring for sealing a protection region therebetween, such as micro electro mechanical systems (MEMS) devices, Si-based devices, GaAs-based devices, InP-based devices. The Si-based devices include a semiconductor memory device including a silicon substrate and poly silicon, and the GaAs-based devices and the InP-based devices include a light emitting device such as light emitting diodes (LEDs) light emitting layers formed of GaAs and InP. Although the photo sensor package is exemplified and the substrate assembly 200 includes the transparent substrate in the embodiments, the present disclosure can be applied to an electronic device package. In this case, the substrate assembly 200 may include an opaque substrate. As such, when the substrate assembly 200 is used in an electronic device package, the substrate assembly 200 may includes a substrate that is formed of at least one selected from the group consisting of Si, Ge, SiGe, GaP, GaAs, SiC, SiGeC, InAs, and InP, and the substrate may be doped with predetermined impurities. That is, the substrate assembly 200 may include an opaque or translucent substrate as well as a transparent substrate, and may include a semiconductor or conductive substrate as well as an insulating substrate. When the substrate assembly 200 includes a conductive substrate, an insulating material may be applied on the conductive substrate.

In accordance with the embodiment, since the sealing layer and the adhesion layer are stacked to form the sealing ring, and the adhesion layer securely adheres the sealing layer to the sealing ring pad on the substrate assembly, the electronic device chip can be securely adhered to the substrate assembly. A lower melting point material having a lower melting point than those of the sealing layer and the sealing ring pad is melted and reacts with the sealing layer and the sealing ring pad to form the adhesion layer. Thus, since the melting point of the adhesion layer is higher than that of the low melting point material layer, and the sealing layer having a high melting point and the adhesion layer are not melted at a high temperature process such as a sub-mount process to be performed later, a defect such as a blowout of the sealing ring can be prevented. Accordingly, the sealing ring can be formed in a closed loop shape, and the introduction of a foreign substance such as dust and moisture from the outside can be efficiently prevented.

In addition, the polymer layer such as a color filter and a microlens is removed in the region provided with the sealing ring, and the sealing ring contacts the passivation layer. Thus, moisture or a foreign substance can be prevented from being introduced to the space between the passivation layer and the polymer layer. Since the sealing ring and the joints are formed on the passivation layer, the sealing ring and the joints can have the same height. Thus, when the sealing ring and the joints are formed at the same time, the joints can fully contact the transparent substrate, thus, preventing an electrical defect due to poor contact of the joints.

Moreover, since the electronic device can be securely coupled to the substrate assembly, the characteristics and service life of the electronic device can be improved, and a typical manufacturing process can be used to improve the productivity thereof. In addition, the present disclosure can be applied to various electronic device packages including a substrate assembly coupled to an electronic chip with a sealing ring surrounding a protection region, as well as to the photo sensor package.

Although an electronic device package and a method of manufacturing the electronic device package have been described with reference to the specific exemplary embodiments, they are not limited thereto. Therefore, it will be readily understood by those skilled in the art that various modifications and changes can be made thereto without departing from the spirit and scope of the present invention defined by the appended claims.

What is claimed is:

1. An electronic device package comprising:
an electronic device including a polymer layer and a passivation layer configured to protect a device layer;
a substrate assembly facing the electronic device; and
a sealing ring formed in a closed loop between the electronic device and the substrate assembly and surrounding a sealing region,
wherein at least one side surface of the sealing ring contacts the polymer layer, and the sealing ring is disposed on the passivation layer.

2. The electronic device package of claim 1, wherein the electronic device comprises a photo sensor, a micro electro mechanical systems (MEMS) device, a silicon-based device, a GaAs-based device, or an InP-based device.

3. The electronic device package of claim 2, wherein the substrate assembly comprises a transparent substrate, a translucent substrate, or an opaque substrate, with respect to light, and
the substrate assembly comprises a conductive substrate, a semiconductor substrate, or an insulating substrate, with respect to electricity.

4. The electronic device package of claim 1, wherein the passivation layer is disposed on an entire region of the electronic device, and
the polymer layer is disposed in the sealing region on the passivation layer.

5. The electronic device package of claim 4, wherein the passivation layer is formed of a single layer or stacked layers comprising one of silicon oxide (SiO₂), tetraethoxysilane (TEOS), silicon nitride (SiN), silicon carbide (SiC), silicon oxynitride (SiON), a diamond mixture, and mixtures thereof.

6. The electronic device package of claim 4, wherein the polymer layer comprises a color filter and a microlens.

7. The electronic device package of claim 1, wherein the sealing ring comprises a stacked structure of a sealing layer and an adhesion layer.

8. The electronic device package of claim 7, wherein the adhesion layer is formed by reacting a low melting point material layer having a lower melting point than that of the sealing layer with the sealing layer, and comprises an intermetallic compound.

9. The electronic device package of claim 8, wherein the sealing layer comprises at least one of Cu, Au, Sn, SnAg, SnAgCu, Ag, and Ni.

10. The electronic device package of claim 8, wherein the low melting point material layer comprises at least one of Sn, SnAg, a stacked structure of Ti/In/Au, Bi, and In.

11. The electronic device package of claim 8, wherein the sealing layer and the low melting point material layer comprise Cu and Sn, Cu and SnAg, Au and a stacked structure of Ti/In/Au, Sn and Bi, SnAg and Bi, SnAgCu and Bi, Ag and In, or Ni and Sn, respectively.

12. The electronic device package of claim 11, wherein the adhesion layer comprises one of CuSn, CuSnAg, AuIn, SnBi, Sn, AgBi, SnAgCuBi, AgIn, and NiSn.

13. The electronic device package of claim 1, further comprising a joint disposed outside the sealing ring and contacting the passivation layer.

14. The electronic device package of claim 1, further comprising a joint disposed inside the sealing ring,
wherein side surfaces of the joint contact the polymer layer, and
a bottom surface of the joint contacts the passivation layer.

15. The electronic device package of claim 1, further comprising a resin seal ring disposed outside the sealing ring.

16. A method of manufacturing an electronic device package, the method comprising:
forming an electronic device including a stacked structure of a passivation layer and a polymer layer on a substrate;
removing a portion of the polymer layer;
stacking a sealing layer and a low melting point material layer on one of the electronic device and a substrate assembly in a region corresponding to the removed portion of the polymer layer;
forming a sealing ring pad on one of the electronic device and the substrate assembly without the sealing layer and the low melting point material layer;
bringing the electronic device in contact with the substrate assembly such that the low melting point material layer corresponds to the sealing ring pad; and
forming an adhesion layer by melting the low melting point material layer and reacting the low melting point material layer with the sealing layer and the sealing ring pad.

17. The method of claim 16, wherein the polymer layer is removed in a closed loop.

18. The method of claim 16, wherein the sealing layer and the low melting point material layer are formed on the electronic device, and
a joint is formed on the passivation layer and is spaced apart from the sealing layer and the low melting point material layer.

19. The method of claim 18, wherein the joint, the sealing layer, and the low melting point material layer are simultaneously formed of an identical material.

20. The method of claim 16, wherein the adhesion layer is heat-treated to have an intermetallic compound different from that of the low melting point material layer.
